(19) United States
(12) Patent Application Publication
(10) Pub. No.: US 2002/0048302 A1
(43) Pub. Date: Apr. 25, 2002

(54) GALLIUM NITRIDE SEMICONDUCTOR LASER AND A MANUFACTURING PROCESS THEREOF

(76) Inventor: AKITAKA KIMURA, TOKYO (JP)

Correspondence Address: SUGHRUE MION ZINN MACPEAK & SEAS, 2100 PENNSYLVANIA AVENUE NW, WASHINGTON, DC, 200373202

(21) Appl. No.: 09/098,433

(22) Filed: Jun. 17, 1998

(30) Foreign Application Priority Data
Jun. 19, 1997 (JP) 162717/97

(51) Int. Cl. H01S 5/00; H01L 21/00

(52) U.S. Cl. 372/46; 372/45

(57) ABSTRACT

A buffer layer 602 and a gallium nitride contact layer 603 are formed on a sapphire (0001) plane substrate 101 by a MOVPE process, and then a silicon nitride mask 102 is formed on the surface. On the silicon nitride mask 102 is formed a rectangular opening whose longer and shorter sides are in the directions of [11-20] and [1-100] of the gallium nitride. On the opening is formed a gallium nitride semiconductor layer 104 by a MOVPE process, whose side face, the (11-20) plane is used as a resonator end face 103.

### BACKGROUND OF THE INVENTION

1. Field of the Invention

This invention relates to a gallium nitride semiconductor laser comprising a resonator mirror with good profile irregularity and parallelism as well as a manufacturing process thereof.

2. Description of the Related Art

Gallium nitride has a larger forbidden band width energy than a conventional common compound semiconductor such as indium phosphide and gallium arsenide. A gallium nitride semiconductor is therefore expected to be applied to a light emitting diode from green to ultraviolet, particularly in laser. Gallium nitride representing gallium nitride semiconductors, has been generally formed on a sapphire substrate having a surface of (11-20) or (0001) plane, using a MOVPE (Metal Organic Vapor Phase Epitaxy) process. FIG. 6 is a schematic cross section of a typical gallium nitride laser of the prior art, formed on a sapphire plane substrate (S.Nakamura et al., Jpn.J.Appl.Phys.35(1996) L74). In the gallium nitride laser in FIG. 6, on a sapphire (0001) plane substrate 101 are formed an undoped low-temperature grown gallium nitride buffer layer 602 with a thickness of 300 Å at a growth temperature of 550° C.; an n-type of gallium nitride contact layer 603 with a thickness of 3 μm containing silicon; an n-type of In_{0.1}Ga_{0.9} layer 604 with a thickness of 0.1 μm containing silicon; an n-type of Al_{0.15}Ga_{0.85}N cladding layer 605 with a thickness of 0.4 μm containing silicon; an n-type of gallium nitride light guiding layer 606 with a thickness of 0.1 μm containing silicon; a multi-quantum-well structure active layer 607 with 26 cycles consisting of an undoped In_{0.2}Ga_{0.8}N quantum-well layer with a thickness of 25 Å and an undoped In_{0.05}Ga_{0.95}N barrier layer with a thickness of 50 Å; a p-type of Al_{0.2}Ga_{0.8}N layer 608 with a thickness of 200 Å containing magnesium; a p-type of gallium nitride light guiding layer 609 with a thickness of 0.1 μm containing magnesium; a p-type of Al_{0.15}Ga_{0.85}N cladding layer 610 with a thickness of 0.4 μm containing magnesium; a p-type of gallium nitride contact layer 611 with a thickness of 0.5 μm containing magnesium; a p-electrode 612 consisting of nickel (the first layer) and gold (the second layer); and an n-electrode 613 consisting of titanium (the first layer) and aluminum (the second layer). A MOVPE process has been used for forming the semiconductor layers of 602, 603, 604, 605, 606, 607, 608, 609, 610 and 611. The semiconductor layers from the layer on the n-type of gallium nitride contact layer 603 to the surface are hexagonal, having a surface of (0001) plane of a gallium nitride semiconductor.

FIG. 7 is a schematic cross section a typical gallium nitride laser of the prior art, formed on a sapphire (1120) plane substrate (S.Nakamura et al., Jpn.J.Appl.Phys.35(1996) L217). In the gallium nitride laser in FIG. 7, on a sapphire (11-20) plane substrate 701 are formed an undoped low-temperature grown gallium nitride buffer layer 702 with a thickness of 500 Å at a growth temperature of 550° C.; an n-type of gallium nitride contact layer 603 with a thickness of 3 μm containing silicon; an n-type of In_{0.1}Ga_{0.9} layer 604 with a thickness of 0.1 μm containing silicon; an n-type of Al_{0.12}Ga_{0.88}N cladding layer 705 with a thickness of 0.4 μm containing silicon; an n-type of gallium nitride light guiding layer 606 with a thickness of 0.1 μm containing silicon; a multi-quantum-well structure active layer 707 with 20 cycles consisting of an undoped In_{0.2}Ga_{0.8}N quantum-well layer with a thickness of 25 Å and an undoped In_{0.05}Ga_{0.95}N barrier layer with a thickness of 50 Å; a p-type of Al_{0.2}Ga_{0.8}N layer 608 with a thickness of 200 Å containing magnesium; a p-type of gallium nitride light guiding layer 609 with a thickness of 0.1 μm containing magnesium; a p-type of Al_{0.15}Ga_{0.85}N cladding layer 610 with a thickness of 0.4 μm containing magnesium; a p-type of gallium nitride contact layer 611 with a thickness of 0.5 μm containing magnesium; a p-electrode 612 consisting of nickel (the first layer) and gold (the second layer); and an n-electrode 613 consisting of titanium (the first layer) and aluminum (the second layer). A MOVPE process has been used for forming the semiconductor layers of 602, 603, 604, 705, 606, 707, 608, 609, 610 and 611. The semiconductor layers from the layer on the n-type of gallium nitride contact layer 603 to the surface are hexagonal, having a surface of (0001) plane of a gallium nitride semiconductor.

Both gallium nitride lasers of the prior art, however, have a problem that it is difficult to form a resonator mirror.

For example, the gallium nitride laser of the prior art shown in FIG. 6 is formed on the sapphire (0001) plane substrate 101. In this laser, the (1-100) plane which is a cleavage plane perpendicular to the surface of the sapphire (0001) plane substrate 101 forms an angle of 30° with the (1-100) plane which is a cleavage plane perpendicular to the surface of the gallium nitride semiconductor layers from the layer on the n-type of gallium nitride contact layer 603 to the surface. Therefore, in a gallium nitride laser formed on the sapphire (0001) plane substrate, it has been difficult to form a resonator mirror by convenient cleavage. Thus, it should be formed by dry etching. For forming the resonator mirror, dry etching has problems such as a more complicated process compared with cleavage, damage in the semiconductor layers and irregularity in the resonator mirror surface.

K.Itaya et al.(Jpn.Appl.Phys.35(1996) L1315) has described that a resonator mirror may be formed using cleavage by grinding a sapphire substrate to a thickness below a certain level, in a gallium nitride laser formed on a sapphire (0001) plane substrate. The process, however, has a problem of a poor yield rate in forming a resonator mirror.

A gallium nitride laser of the prior art as shown in FIG. 7 is formed on the sapphire (11-20) plane substrate 701. In this laser, the (1-100) plane which is a cleavage plane perpendicular to the surface of the sapphire (11-20) plane substrate 701 is almost parallel to the (1-100) plane which is a cleavage plane perpendicular to the surface of the gallium nitride semiconductor layers from the layer on the n-type of gallium nitride contact layer 603 to the surface. It is, therefore, possible to form a resonator mirror by cleavage in a relatively good yield rate, in a gallium nitride laser formed on the sapphire (11-20) plane substrate. However, since the cleavage planes of the sapphire substrate are not exactly parallel to the gallium nitride semiconductor layers (forming 2.40 tilt), irregularity in the resonator mirror may be generated.

For providing a semiconductor laser having good vibration threshold current and vibration efficiency, it is necessary to improve profile irregularity and parallelism of a resonator mirror. However, as described above, a conventional gallium nitride laser has not adequately meet the conditions. Furthermore, since a complicated process such as dry etching is required for improving parallelism of the resonator mirror, it has been strongly desired to develop a process for forming a good resonator mirror in a convenient procedure.

### SUMMARY OF THE INVENTION

This invention, which can solve the above problems, provides a semiconductor laser comprising a substrate on which a resonator having a gallium nitride semiconductor layer is formed, wherein the gallium nitride semiconductor layer has a hexagonal crystal structure; the end face of the resonator is the (11-20) plane of the gallium nitride semiconductor layer and is formed substantially perpendicular to the substrate; and the end face has a profile irregularity of several-atom layer level. This semiconductor laser is improved in parallelism and profile irregularity of both end faces constituting the resonator, and thus can achieve an improved threshold current and vibration efficiency.

This invention also provides a process for manufacturing a semiconductor laser comprising a gallium nitride semiconductor layer, comprising the following steps: forming a flat layer comprising one or more gallium nitride semiconductor layers which has a hexagonal crystal structure and whose principal plane is a (0001) plane of the crystal structure or a plane forming an angle within 5° with the (0001) plane, on the substrate directly or via a buffer layer; forming a silicon nitride mask on the surface of the flat layer; forming a rectangular opening having longer and shorter sides in the [11-20) and [1-100] directions of the flat layer, respectively, on the silicon nitride mask; and forming a selective growth layer comprising one or more gallium nitride semiconductor layers including an active layer, on the surface of the flat layer on the opening.

Epitaxial growth of a gallium nitride semiconductor layer has been conventionally conducted by selective growth using silicon oxide as a mask. However, in this process, it has been difficult to make a side face of the selective growth layer perpendicular to the substrate. Even if a perpendicular side face can be formed, it has requires extremely stringent manufacturing conditions, giving a poor quality stability. Thus, a resonator mirror has been generally formed by dry etching or cleavage after forming a selective growth layer. In contrast, the process of this invention grows silicon nitride as a mask, so that the side face of the selective growth layer is substantially perpendicular to the substrate; and provides a smooth mirror surface with a profile irregularity of several-atom layer level. Thus, since the side face of the selective growth layer may be a resonator mirror as it is, a resonator mirror with good parallelism, profile irregularity and quality stability may be provided without significant restriction to the manufacturing conditions.

The semiconductor laser of this invention has a resonator side face substantially perpendicular to the substrate and the side face has a profile irregularity of several-atom layer level. The laser can, therefore, achieve a good threshold current and a vibration efficiency.

The semiconductor laser of this invention uses the (11-20) plate of the gallium nitride semiconductor layer as a resonator end face, which can be thus formed by, for example, epitaxial growth using silicon nitride as a mask. It can, therefore, achieve a good quality stability without significant restriction to the manufacturing conditions.

In the process for manufacturing a semiconductor laser of this invention, silicon nitride is grown as a mask to form a side face of the selective growth layer substantially perpendicular to the substrate and a smooth mirror surface having a profile irregularity of several-atom layer level. The side face of the selective growth layer may be a resonator mirror as it is. It may also eliminate necessity for forming the resonator mirror by dry etching or cleavage with a poor yield rate. Furthermore, it does not generate irregularity on the resonator mirror. In other words, the process for manufacturing a gallium nitride laser of this invention may form a considerably smooth resonate mirror with good parallelism by a convenient procedure, and has an advantage that there is less restriction to the manufacturing conditions and its quality stability is improved.

### BRIEF DESCRIPTION OF THE DRAWINGS

FIG. 1 is a schematic cross section showing a structure of a gallium nitride laser of this invention.

FIG. 2 is a schematic cross section showing a layer structure of a selective growth layer of a gallium nitride laser of this invention.

FIG. 3 is a schematic cross section showing a layer structure of a selective growth layer of another gallium nitride laser of this invention.

FIG. 4 is a schematic cross section showing a structure of another gallium nitride laser of this invention.

FIG. 5 is a schematic cross section showing a structure of a gallium nitride laser of this invention.

FIG. 6 is a schematic cross section of a typical gallium nitride laser formed on a (0001) plane sapphire substrate by a crystal growth process of the prior art.

FIG. 7 is a schematic cross section of a typical gallium nitride laser formed on a (11-20) plane sapphire substrate by a crystal growth process of the prior art.

### DETAILED DESCRIPTION OF THE PREFERRED EMBODIMENTS

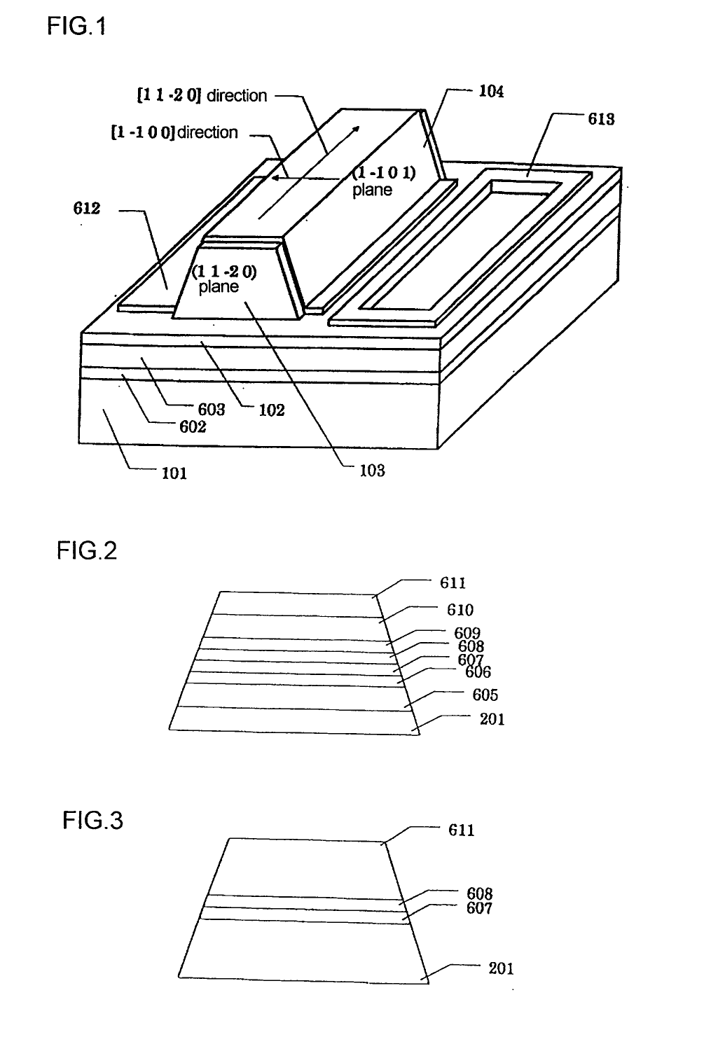

An embodiment of the semiconductor laser of this invention will be described with reference to FIG. 1.

Materials for the substrate 101 in this invention include sapphire, GaN, Si and SiC. Among others sapphire is preferable because it may permit a relatively easy formation of a gallium nitride semiconductor layer with a good crystallization property. Using sapphire, a principal plane of the substrate should be a (0001) or (11-20) plane.

A gallium nitride semiconductor layer in this invention refers to a semiconductor layer represented by a general formula of InₓAlyGa_{l-x-y}N (0≦x≦1, 0≦y≦1, 0≦x+y≦1).

In the semiconductor laser of this invention, the resonator end face 103 is substantially perpendicular to the substrate 101. “Substantially perpendicular” means that the face is sufficiently perpendicular to avoid reduction of the vibration efficiency. Specifically, the resonance end face 103 is formed at an angle within 1°, preferably within 0.5° to the direction perpendicular to the substrate 101, which results in a good resonance threshold current and a vibration efficiency.

In the semiconductor laser of this invention, the resonator end face 103 has a profile irregularity of several-atom layer level. A profile irregularity of several-atom layer level refers to a irregularity of 2 to 3 atom layer level, which is comparable to a mirror surface formed by a cleavage process, a conventional mirror formation process. Such a profile irregularity may provide a good threshold current and a vibration efficiency.

In the semiconductor laser of this invention, the gallium nitride semiconductor layer 104 has a hexagonal crystal structure, and the resonator end face 103 is the (11-20) plane of the gallium nitride semiconductor layer 104, resulting in retention of perpendicularity of the resonator end face 103 and the substrate 101. Furthermore, utilizing the (11-20) plane makes it possible to form it by, for example, epitaxial growth using silicon nitride as a mask, as described later. Therefore, a semiconductor laser having good quality stability may be provided without significant restriction to the manufacturing conditions.

The resonator end face 103 is preferably the side face of the gallium nitride semiconductor layer 104 formed by epitaxial growth of the gallium nitride semiconductor layer 104 on the substrate 101. In other words, a particularly excellent profile irregularity and parallelism may be achieved by employing the side face of the selective growth layer during epitaxial growth of the gallium nitride semiconductor layer on the substrate under predetermined conditions by appropriately selecting a mask material. The mask used in epitaxial growth may include silicon oxide, gallium nitride and titanium dioxide, preferably silicon nitride because a resonator end face substantially perpendicular to the substance as described later may be readily formed.

An embodiment of the process for manufacturing a semiconductor laser of this invention will be described with reference to FIG. 1. In the process for manufacturing a semiconductor of this invention, a gallium nitride contact layer (flat layer) 603 is formed on a substrate 101 directly or via a buffer layer 602. A buffer layer refers to a layer for forming an even monocrystal of gallium nitride semiconductor on it. It may be partially monocrystallized during temperature rising and the crystallized part becomes a core for accelerating even growth of the monocrystal. The flat layer 603 has a hexagonal crystal structure, and its principal plane is a (0001) plane of its crystal structure or a plane forming an angle within 5° to the (0001) plane. Employing such a plane as a principal plane may lead to a resonator end face 103 perpendicular to the substrate in forming a gallium nitride semiconductor layer on the flat layer 603. If the angle formed with the (0001) plane is more than 5°, parallelism of the resonator end face 103 may be lost.

A gallium nitride mask 102 is formed on the surface of the flat layer 603. A thickness of the gallium nitride mask is preferably, but not limited to, at least 500 Å to up to 4000 Å, more preferably at least 1000 Å to up to 3000 Å. If it is less than 500 Å, the mask may have defects such as pinholes. A thickness more than 4000 Å may not indicate a significantly improved effect. It is, therefore, adequate to select a thickness up to 4000 Å.

The silicon nitride mask 102 may be formed using a common process such as a CVD process and usual conditions. A composition ratio maybe deviated from a stoichiometric ratio within a range where no defects such as pinholes are generated in the mask.

The mask has an opening whose longer and shorter sides are [11-20] and [1-100] directions of the flat layer, respectively. The size of the opening is determined in the light of the size of the resonator as appropriate.

After forming the opening, a selective growth layer comprising one or more gallium nitride semiconductor layers including an active layer is formed on the surface of the flat layer 603 around the opening. It may be preferably formed by an organic metal chemistry gaseous phase growth method, which are conducted under common growth conditions; for example, at a temperature of 900 to 1200° C.

Examples of a layer structure of the selective growth layer are illustrated in FIGS. 2, 3 and 5. The selective growth layer preferably consists of only layers not containing aluminum as shown in FIGS. 3 and 5 because when a gallium nitride semiconductor layer containing AlGaN is formed by a selective growth process, polycrystalline AlGaN may be deposited on the mask due to reaction of the mask material with a starting material containing Al. When such a layer structure is employed, an AlGaN cladding layer is not contained in the selective growth layer. It is, therefore, preferable to take a means for ensuring some degree of light-enclosure coefficient in a multiple quantum well active layer 607. An effective example of the means is that the multiple quantum well structure is of relatively many cycles. For example, the cycle number is preferably at least 8 for a multiple quantum well structure consisting of an In_{0.2}Ga_{0.8}N quantum well layer and an In_{0.05}Ga_{0.95}N barrier layer. It may be also effective to form an AlₓGa₁₋ₓN(0≦x≦1) cladding layer in the flat layer beneath the mask. For example, an n-type of AlGaN cladding layer 405 may be formed between an n-type of gallium nitride contact layer 603 an a silicon nitride mask 102, as shown in FIG. 3. In FIG. 3, a flat layer consists of an n-type of gallium nitride contact layer 603 and an n-type of AlGaN cladding layer 405. This process may ensure a light-enclosure coefficient without significant increase of the cycle number of the multiple quantum well structure.

### EXAMPLE 1

This invention will be specifically described with reference to the following examples.

In this example, a resonator mirror of the gallium nitride laser is the (11-20) plane which is the side face of the gallium nitride semiconductor layer formed by selective growth using silicon nitride as a mask material.

FIG. 1 is a schematic cross section of the structure of the gallium nitride laser of this example. The gallium nitride laser was prepared as follows. An undoped low-temperature grown gallium nitride buffer layer 602 with a thickness of 300 Å grown at a growth temperature of 550° C. and an n-type of gallium nitride contact layer 603 with a thickness of 3 μm containing silicon were formed on a sapphire (0001) plane substrate 101, byaMOVPE process. The n-type of gallium nitride contact layer 603 is a hexagonal crystal whose surface is the (0001) plane. Then, a silicon nitride mask 102 with a thickness of 2000 Å which has a rectangular opening with a size of 500 μm and 5 μm in the directions of [11-20] and [1-100] of the gallium nitride, respectively, was formed on the surface of the n type of gallium nitride contact layer 603, by a plasma chemical vapor deposition (plasma CVD), lithography and etching with hydrofluoric acid. Then, a gallium nitride semiconductor layer containing an active layer for a gallium nitride laser was selectively formed only around the opening of the mask 102 by a MOVPE process. Finally, a p-electrode 612 consisting of nickel (the first layer) and gold (the second layer); and an n-electrode 613 consisting of titanium (the first layer) and aluminum (the second layer) were formed. The gallium nitride laser of Example 1 shown in FIG. 1 employs the (11-20) plane of gallium nitride formed on the side face of the gallium nitride semiconductor layer 104, as a resonator mirror.

FIG. 2 shows a schematic cross section of the gallium nitride semiconductor layer 104 shown in FIG. 1, taken on the (11-20) plane of gallium nitride in this example. In FIG. 2, a gallium nitride semiconductor crystal 103 consists of an n-type of gallium nitride layer 201 with a thickness of 0.4 μm containing silicon; an n-type of Al_{0.15}Ga_{0.85}N cladding layer 605 with a thickness of 0.4 μm containing silicon; an n-type of gallium nitride light guiding layer 606 with a thickness of 0.1 μm containing silicon; a multi-quantum-well structure active layer 607 with 26 cycles consisting of an undoped In_{0.2}Ga_{0.8}N quantum-well layer with a thickness of 25 Å and an undoped In_{0.05}Ga_{0.95}N barrier layer with a thickness of 50 Å; a p-type of Al_{0.2}Ga_{0.8}N layer 608 with a thickness of 200 Å containing magnesium; a p-type of gallium nitride light guiding layer 609 with a thickness of 0.1 μm containing magnesium; a p-type of Al_{0.15}Ga_{0.85}N cladding layer 610 with a thickness of 0.4 μm containing magnesium; and a p-type of gallium nitride contact layer 611 with a thickness of 0.5 μm containing magnesium.

In this example, silicon nitride is used as a mask material for forming the selective growth layer of the gallium nitride semiconductor, and the gallium nitride semiconductor layer 104 is surrounded by the (0001), the (1-101) and the (11-20) planes. Since the mask 102 has a rectangular opening with a longer side in the direction of [11-20] of gallium nitride, the (11-20) plane which is a side face of the gallium nitride semiconductor layer 104, may be a resonator mirror for the laser as it is.

It was found by SEM observation that the resonator end face 103 was formed at a right angle to the substrate and has a profile irregularity of several-atom layer level.

### EXAMPLE 2

As described in Example 1, a resonator mirror of the gallium nitride laser is the (11-20) plane which is the side face of the gallium nitride semiconductor layer formed by selective growth using silicon nitride as a mask material. In this example, there are no AlGaN cladding layers as were formed on and beneath the active layer of the gallium nitride semiconductor layer 104 in Example 1.

FIG. 1 is again a schematic cross section of the structure of the gallium nitride laser. A manufacturing process was also similar in this example.

FIG. 3 shows a schematic cross section of the gallium nitride semiconductor crystal 103 shown in FIG. 1, taken on the (11-20) plane of gallium nitride in this example. In FIG. 3, a gallium nitride semiconductor crystal 103 consists of an n-type of gallium nitride layer 201 with a thickness of 0.9 μm containing silicon; a multi-quantum-well structure active layer 607 with 26 cycles consisting of an undoped In_{0.2}Ga_{0.8}N quantum-well layer with a thickness of 25 Å and an undoped In_{0.05}Ga_{0.95}N barrier layer with a thickness of 50 Å; a p-type of Al_{0.2}Ga_{0.8}N layer 608 with a thickness of 200 Å containing magnesium; and a p-type of gallium nitride contact layer 611 with a thickness of 1.0 μm containing magnesium.

In this example, since the mask 102 has a rectangular opening with a longer side in the direction of [11-20] of gallium nitride, the (11-20) plane of the gallium nitride semiconductor layer 104 formed by a selective growth process, may be a resonator mirror for the laser as it is.

It was found by SEM observation that the resonator end face 103 was formed at a right angle to the substrate and has a profile irregularity of several-atom layer level.

### EXAMPLE 3

As described in Examples 1 and 2, a resonator mirror of the gallium nitride laser is the (11-20) plane which is the side face of the gallium nitride semiconductor layer formed by selective growth using silicon nitride as a mask material. In this example, there are no AlGaN cladding layers as were formed on and beneath the active layer of the gallium nitride semiconductor layer 104 in Example 1, and there is an n-type of AlGaN cladding layer between the n-type of gallium nitride contact layer 603 and the silicon nitride mask 102. In other words, a flat layer consists of an n-type of gallium nitride contact layer 603 and an n-type of AlGaN cladding layer 405.

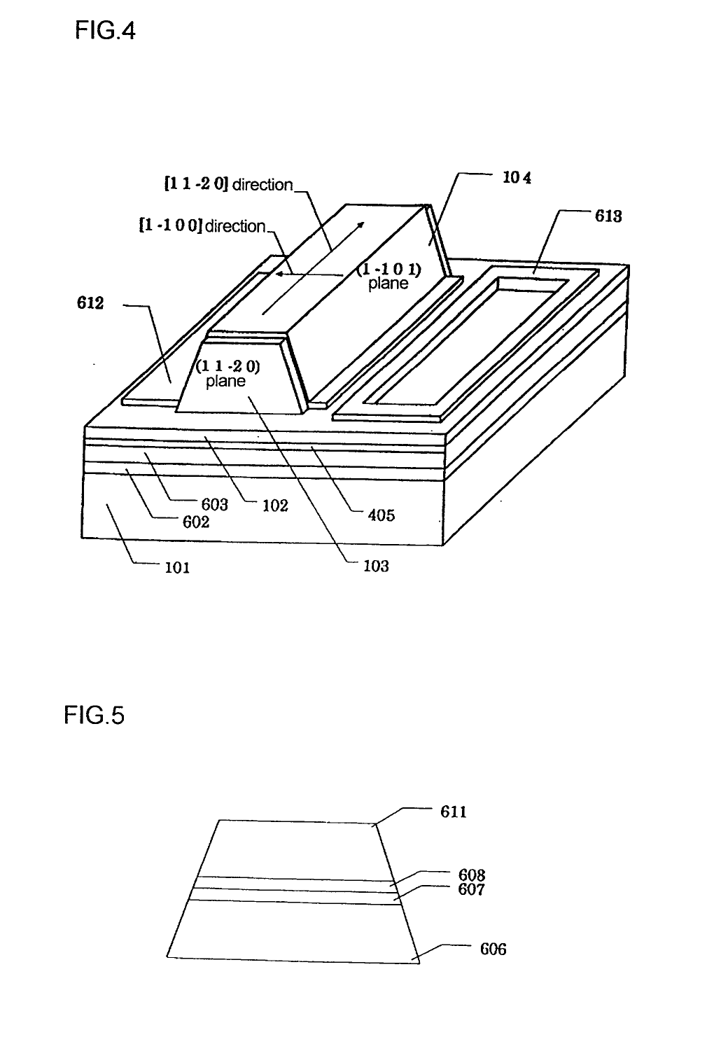

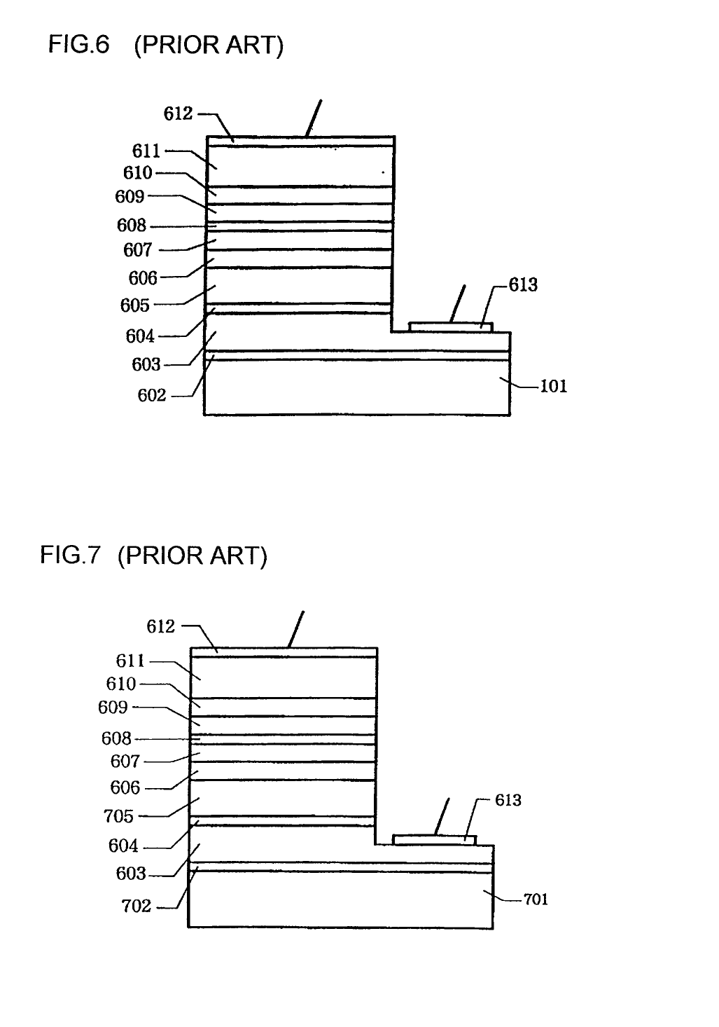

FIG. 4 is a schematic cross section of the structure of the gallium nitride laser of this example. The gallium nitride laser of this invention shown in this figure was prepared as follows. On a sapphire (0001) plane substrate 101 were formed an undoped low-temperature grown gallium nitride buffer layer 602 with a thickness of 300 Å grown at a growth temperature of 550° C. by a MOVPE process; an n-type of gallium nitride contact layer 603 with a thickness of 3 μm containing silicon; an n-type of Al_{0.15}Ga_{0.85}N cladding layer 405 with a thickness of 0.4 μm containing silicon. The n-type of gallium nitride contact layer 603 and the n-type of Al_{0.15}Ga_{0.85}N cladding layer 405 are hexagonal crystals whose surface is the (0001) plane. Then, a silicon nitride mask 102 with a thickness of 2000 Å which has a rectangular opening with a size of 500 μm and 5 μm in the directions of [11-20] and [1-100] of the gallium nitride, respectively, was formed on the surface of the n-type of gallium nitride contact layer 603, by a plasma chemical vapor deposition (plasma CVD), lithography and etching with hydrofluoric acid. Then, a gallium nitride semiconductor layer 104 containing an active layer for a gallium nitride laser was selectively formed only around the opening of the mask 102 by a MOVPE process. Finally, a p-electrode 612 consisting of nickel (the first layer) and gold (the second layer); and an n-electrode 613 consisting of titanium (the first layer) and aluminum (the second layer) were formed. The gallium nitride laser of this example shown in FIG. 1 employs the (11-20) plane of gallium nitride formed on the side face of the gallium nitride semiconductor layer 104, as a resonator mirror.

FIG. 5 shows a schematic cross section of the gallium nitride semiconductor layer 104 shown in FIG. 4, taken on the (11-20) plane of gallium nitride in this example. In FIG. 5, a gallium nitride semiconductor crystal 103 consists of an n-type of gallium nitride light guiding layer 606 with a thickness of 0.1 μm containing silicon; a multi-quantum-well structure active layer 607 with 26 cycles consisting of an undoped In_{0.2}Ga_{0.8}N quantum-well layer with a thickness of 25 Å and an undoped In_{0.05}Ga_{0.95}N barrier layer with a thickness of 50 Å; a p-type of Al_{0.2}Ga_{0.8}N layer 608 with a thickness of 200 Å containing magnesium; and a p-type of gallium nitride contact layer 611 with a thickness of 1.0 μm containing magnesium.

In this example, since the mask 102 has a rectangular opening with a longer side in the direction of ([11-20] of gallium nitride, the (11-20) plane of the gallium nitride semiconductor layer 104 formed by a selective growth process, may be a resonator mirror for the laser as it is.

It was found by SEM observation that the resonator end face 103 was formed at a right angle to the substrate and has a profile irregularity of several-atom layer level.

A gallium nitride laser of this invention and a manufacturing process thereof should be not construed to be effective only to the mask patterns and the layer structures shown in Examples 1 to 3, but construed to be effective to any type of mask pattern or layer structure without departing from the spirit and scope of this invention. A surface orientation of the sapphire substrate in this invention should not be necessarily the (0001) plane as described in Examples 1 to 3, and maybe the (11-20) plane. Furthermore, the surface orientation of the sapphire substrate should not be necessarily the (0001) or (11-20) plane in a strict sense. A plane forming an angle within about 5° with the (0001) or (11-20) plane may be acceptable. A direction of the longer or shorter side of the rectangular opening in the mask should not be necessarily the [11-20] or [1-100] direction of the gallium nitride in a strict sense. A direction forming an angle within about 5° with the [11-20] or [1-100] direction may be acceptable.

What is claimed is:

1. A semiconductor laser comprising a substrate on which a resonator having a gallium nitride semiconductor layer is formed, wherein the gallium nitride semiconductor layer has a hexagonal crystal structure; the end face of the resonator is the (11-20) plane of the gallium nitride semiconductor layer and is formed substantially perpendicular to the substrate; and the end face has a profile irregularity of several-atom layer level.

2. A semiconductor laser as is claimed in claim 1, wherein the end face is a side face of the gallium nitride semiconductor layer formed by epitaxial growth on the substrate.

3. A semiconductor laser as is claimed in claim 1, wherein the substrate is a sapphire substrate.

4. A semiconductor laser as is claimed in claim 1, wherein the substrate is a sapphire substrate on which a flat layer comprising one or more gallium nitride semiconductor layers is formed; the flat layer has a hexagonal crystal structure; and the principal plane of the flat layer is a (0001) plane of the crystal structure or a plane forming an angle within 5° with the (0001) plane.

5. A process for manufacturing a semiconductor laser comprising a gallium nitride semiconductor layer, comprising the following steps:
forming a flat layer comprising one or more gallium nitride semiconductor layers which has a hexagonal crystal structure and whose principal plane is a (0001) plane of the crystal structure or a plane forming an angle within 5° with the (0001) plane, on the substrate directly or via a buffer layer;
forming a silicon nitride mask on the surface of the flat layer; forming a rectangular opening having longer and shorter sides in the [11-20] and [1-100] directions of the flat layer, respectively, on the silicon nitride mask;
and forming a selective growth layer comprising one or more gallium nitride semiconductor layers including an active layer, on the surface of the flat layer on the opening.

6. A process for manufacturing a semiconductor laser as is claimed in claim 5, wherein the selective growth layer consists of only layers not containing aluminum.

7. A process for manufacturing a semiconductor laser as is claimed in claim 6, wherein the flat layer comprises a semiconductor layer of AlₓGa₁₋ₓN (0<x<1).

8. A process for manufacturing a semiconductor laser as is claimed in claim 5, wherein the selective growth layer is formed by an organic metal chemistry gaseous phase growth method.

9. A semiconductor laser produced by a process for manufacturing a semiconductor laser as is claimed in claim 5.
